(19) United States
(12) Patent Application Publication
(10) Pub. No.: US 2008/0169401 A1
(43) Pub. Date: Jul. 17, 2008

(54) Flat-Panel Monitor Holder

(76) Inventor: Geoffrey Alan Fryer, Ravena, NY (US)

Correspondence Address: DELAIN & LIEBERT, PLLC, 400 CLIFTON CORPORATE PARKWAY, SUITE 470, CLIFTON PARK, NY, 12065, US

(21) Appl. No.: 11/623,717

(22) Filed: Jan. 16, 2007

(51) Int. Cl. H05K 7/14

(52) U.S. Cl. 248/323; 248/339; 248/343; 248/333; 248/326

(57) ABSTRACT

A portable holder for a monitor is taught, whereby a flat-panel monitor can be suspended in a portable holder from a ceiling or from a vertical object. The holder comprises a body, a mechanism for holding a monitor and the body together, a stem with a ball-type terminus, an optional attachment, and a mechanism for suspending the monitor holder from a ceiling, using the stem, or a vertical object, using the optional attachment.

### BACKGROUND OF THE INVENTION

1. Field of the Invention

This invention relates to monitor stands and holders, specifically suspended monitor stands and holders.

2. Description of the Related Art

U.S. Pat. No. 5,398,991 teaches a video display device having a screen held on its overall surface and flat on the whole is supported on an arm rest of a passenger seat having a recessed part to store, and it is held on a first end part of an angled support arm having first and second end parts and having at least the same length as length of a side surface free to revolve. Additionally, it is furnished with a first revolving means free to revolve the device with respect to the arm between a specified audio visual position and a position where the side surface of the device and the arm stand roughly in parallel with each other and become roughly a square shape to be stored in a recessed part and a second revolving means to hold the second end part of a front part of the arm rest free to revolve and to revolve the arm and the device inside and outside of the recessed part of the arm rest .

U.S. Pat. No. 5,398,903 teaches a video display unit such as a monitor of cathode-ray tubes has a mechanism in which its swivelling and tilting can be adjusted by a user. The display unit has a stable posture independently, when the display unit is separated from a stand including a truncated member having a partial spherical section downwardly protruded, the partial spherical section being located at the inner side of the opening of the bottom cover, and a socket for supporting the display unit while tilting and swivelling.

U.S. Pat. No. 6,098,936 teaches an adjustable computer work stand that will allow for convenient computer component placement for an individual in a non-conventional work environment. The work stand is portable and includes multiple adjustable support elements that can independently support the computer components including the keyboard, video monitor and CPU. The work stand can be adjusted to position a pair of support arms on which the components are placed to be accessible to the user in a reclining chair or other non-conventional work environment.

U.S. Pat. No. 6,100,942 teaches an organizer apparatus for use with a computer monitor. The organizer apparatus has a base which is sized and shaped to rest on top of the computer monitor. The base has a bracket reception means, preferably a slot through either side of the base. The base includes, in various embodiments, a variety of storage devices in several different configurations, including a media storage bin for CD-ROMs. The base preferably further includes a CR-ROM and 3.5-inch floppy drive. A pair of brackets engage with the base in opposing locked positions. Each of the brackets includes an upper horizontal portion for engagement with the base, a vertical portion for laying adjacent to 1 side of the video monitor and a lower horizontal portion having the speaker supporting stand. In the preferred embodiment, the organizer apparatus further includes a folder bin bonded to the monitor with 2-sided adhesive tape and positioned between the vertical portion of at least 1 of the brackets. The folder bin means is designed for accepting paper folder storage.

EPO Patent No. FR2770725 teaches the direct mounting on the work surface of, reducing the encumbrance caused by, the monitor. The monitor includes a liquid crystal flat display screen and a base which is intended to be fastened to a horizontal support. An arm links together the monitor panel and the base with an articulated joint at each end of the arm. Either the base or the arm may then include the necessary circuit to operate the display and provide the current supply. This circuit may include a video signal processing circuit. The base includes sockets, for connection to computer equipment, and a receiver for IR control signals.

EPO Patent No. JP11219127 teaches a display part body part and a stand are connected by connecting parts a, b. The connecting parts a, b have rotary shafts, so that the angles can be optionally adjusted. The display part body part, the stand and a support are placed in plane shape by rotating the display part body part and the stand in the specified direction. A cable is wired to come out from the stand via the support from the display part body part so as to come out downward without hindrance to wall hanging. In fitting structure for wall hanging, a fitting hole is provided in the back face of the display part body part, and a wall is provided with 1 or a plurality of wall hooks to fix. Cabinet structure usable as a desk top type or a wall hanging type can thus be obtained.

Canadian Patent No. 0261984 teaches an adjustable stand including at least one support and at least one adjustable bracket engaged with and adjustable along the support. The adjustable bracket includes a recess in a surface adjacent to the support and at least 1 protrusion extending from a surface of the recess. The adjustable stand also includes at least one mounting bracket including: at least 1 retaining portion configured to interface with a device to be supported by the adjustable stand; and at least one flange portion configured to engage with the recess and the protrusion.

Canadian Patent No. 01154418 teaches a stand for television sets comprising a pair of inverted T-shaped leg sections each comprising a pair of leg members f L-shaped configuration which interengage and nest to form a four-legged base. An elongated bolt member is fixed at the head end to tent the leg sections and has a threaded end projecting beyond the base. When the leg sections are nested, the bolt is disposed in a concealed elongated cavity defined by the leg sections. A closure cap assembly is mounted at the upper terminal end of 1 of the vertical portions of 1 of the leg sections and forms an integral subassembly therewith. The overcap assembly has a configuration and arrangement to vertically align the leg members relative to 1 another and provide a certain parallelism of the parts so that all the bearing surfaces are parallel to 1 another and to the support surface such as a floor. A tray to which the television set is locked by conventional security fasteners is supported on the closure cap and is adapted for limited rotational movement thereto.

The need is felt for a monitor stand or holder that is suspended from an easily portable ceiling or wall fixture and that holds a monitor close enough to a human user, whether that user is sitting, standing or lying down, for the user to be able to interact with the monitor in an application such as a computer game, or for the monitor to occupy more than 50% of the user's field of vision for an application such as a television show or movie.

### BRIEF DESCRIPTION OF THE DRAWINGS

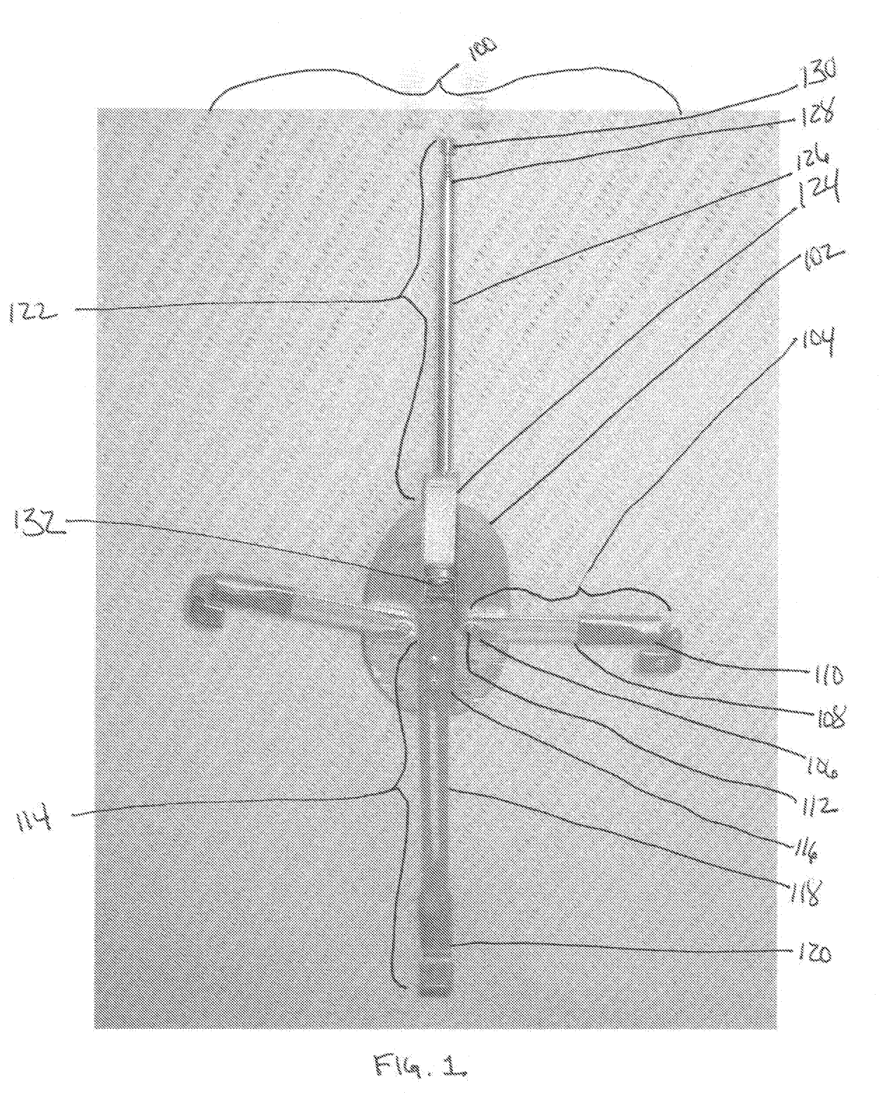

Referring now to FIG. 1, an outside view of a suspendable, portable monitor holder 100 is shown.

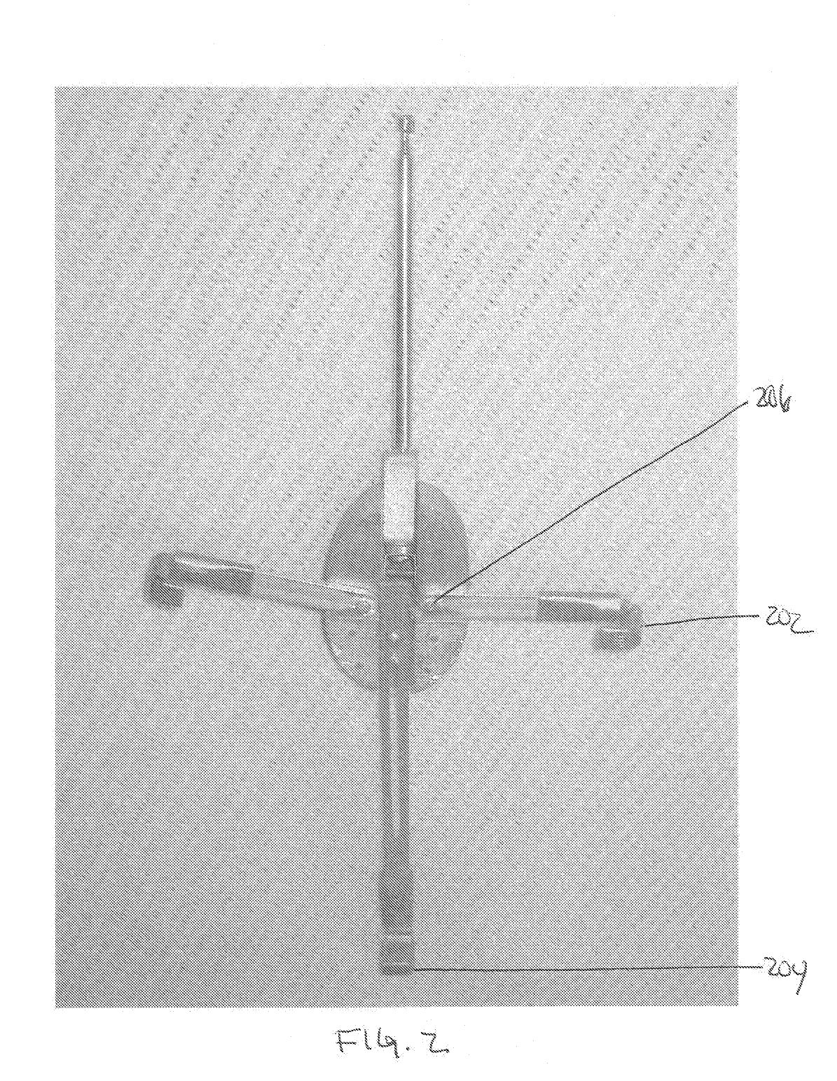

Referring now to FIG. 2, an inside view of a monitor holder 100 is shown.

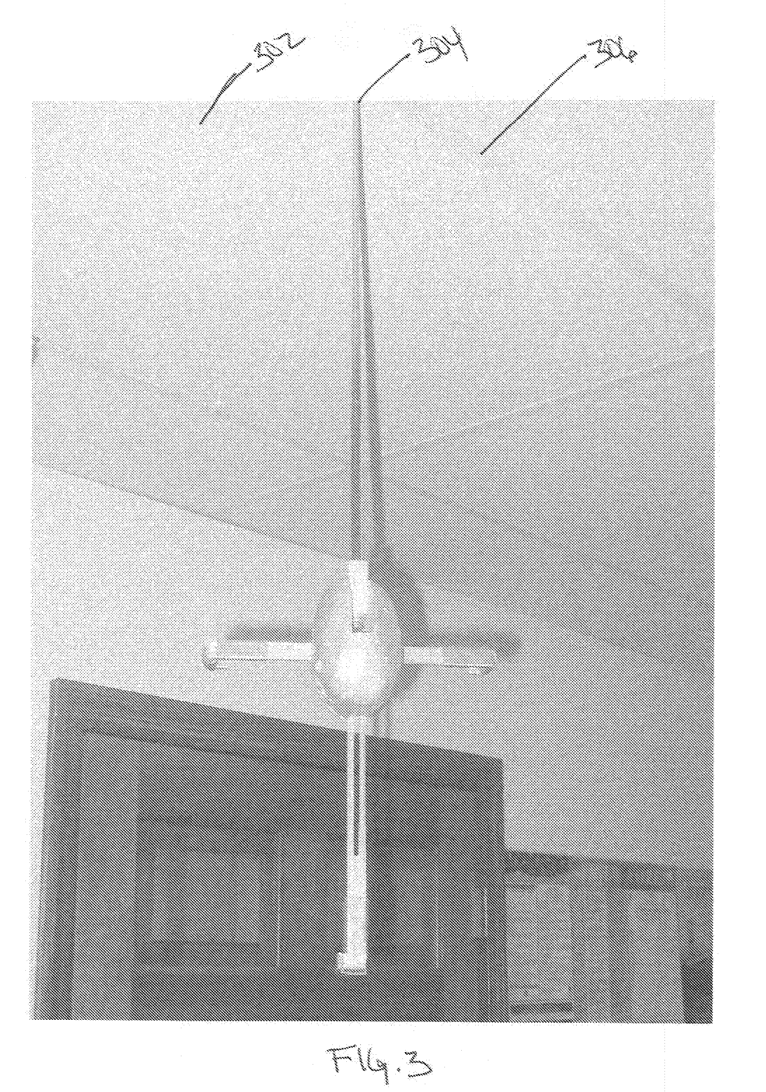

Referring now to FIG. 3, a monitor holder 100 suspended by a stem 122 from a ceiling is shown.

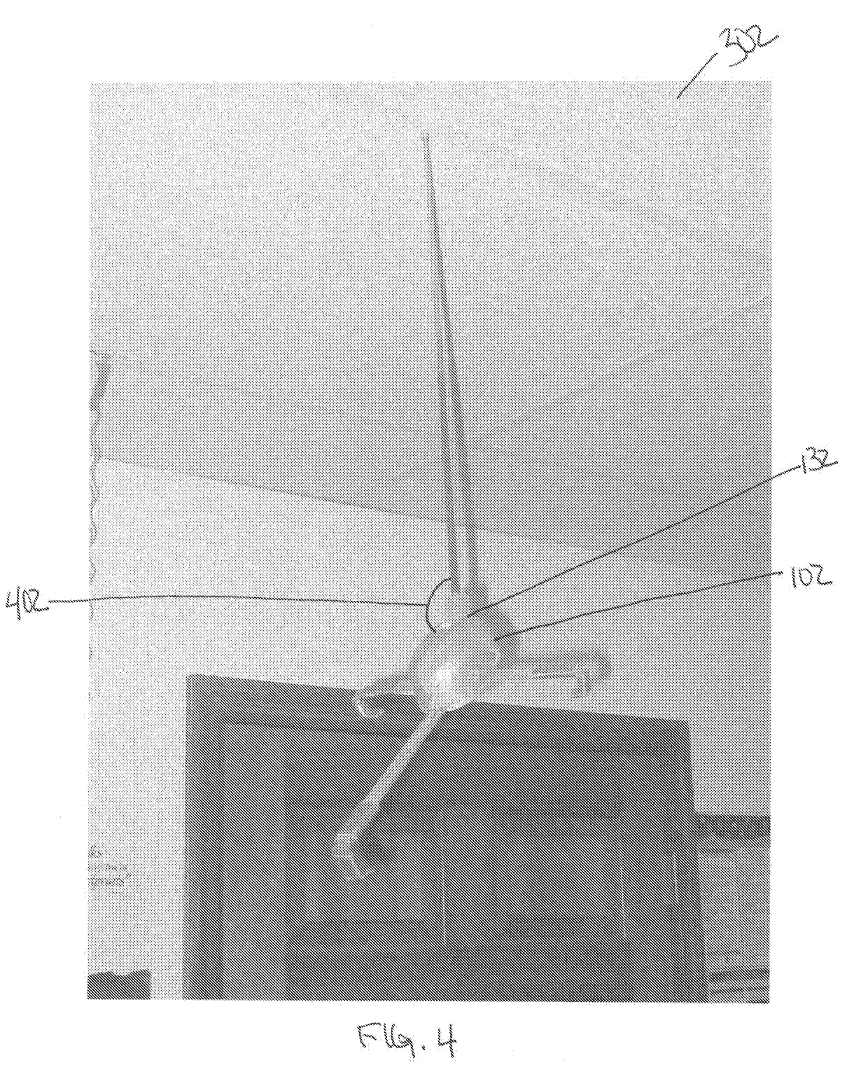

Referring now to FIG. 4, a monitor holder 100 hanging from a ceiling 302 and held by a stem hinge 132 is shown.

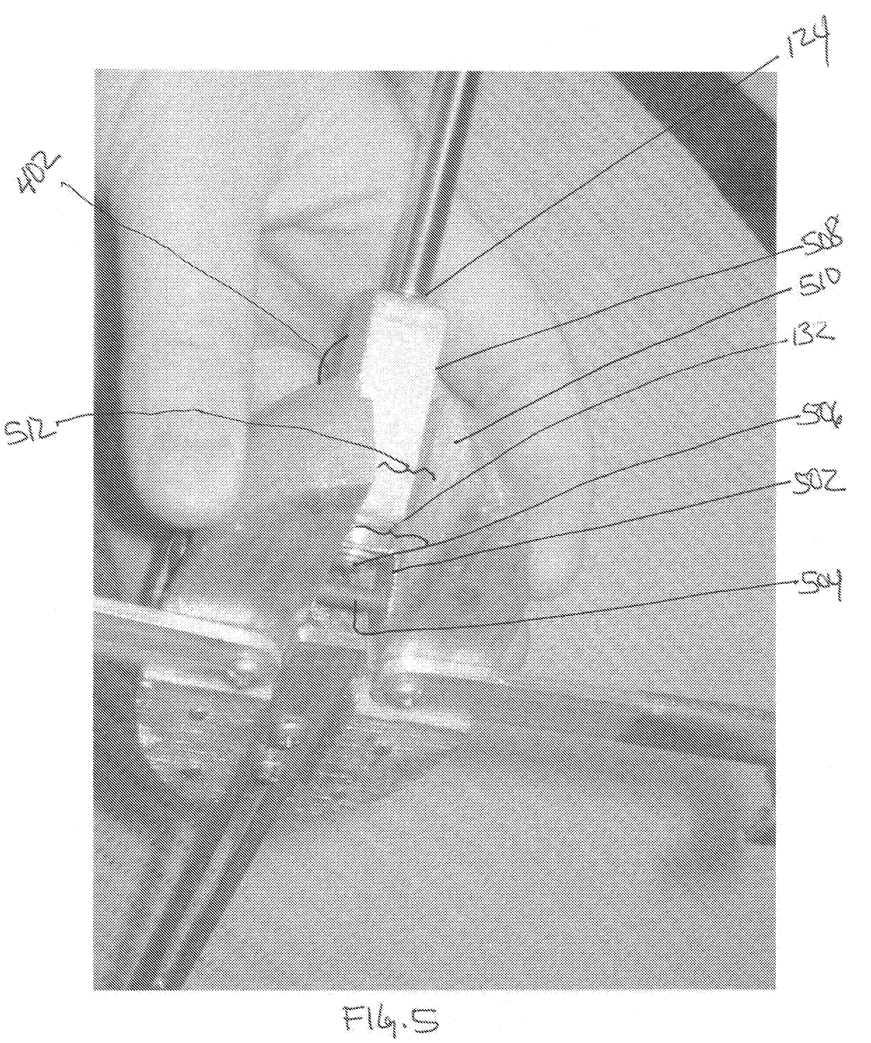

Referring now to FIG. 5, a hinge in the body of a monitor holder is shown.

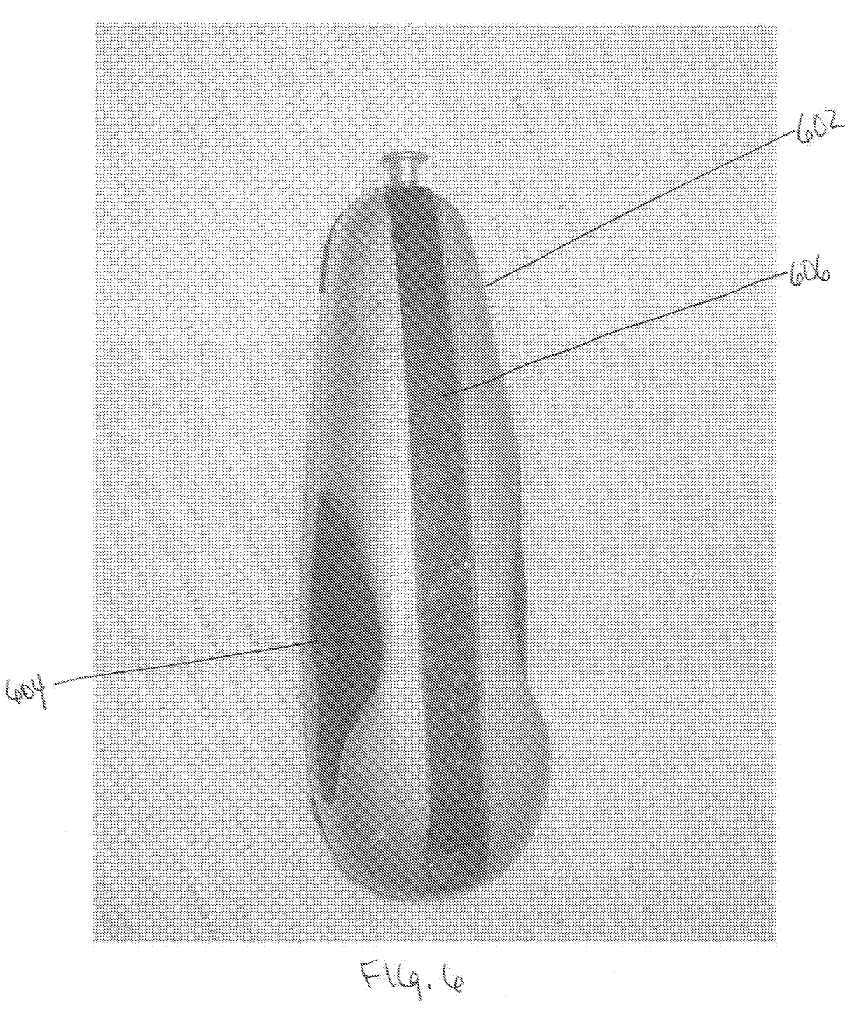

Referring now to FIG. 6, a casing 602 in which a monitor holder 100 can be easily stored and transported is shown.

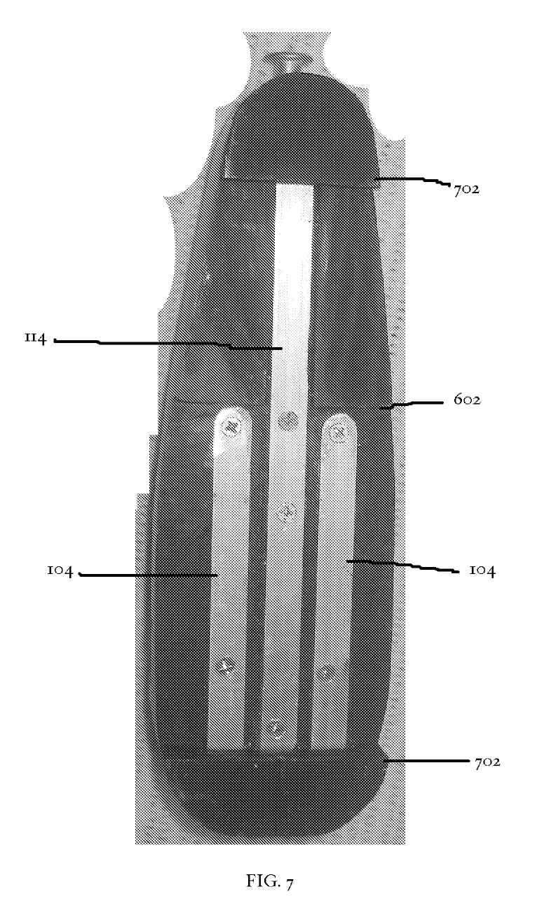

Referring now to FIG. 7, a casing 602 is shown. A monitor holder 100 is held in place within the casing 602 by a set of holders 702.

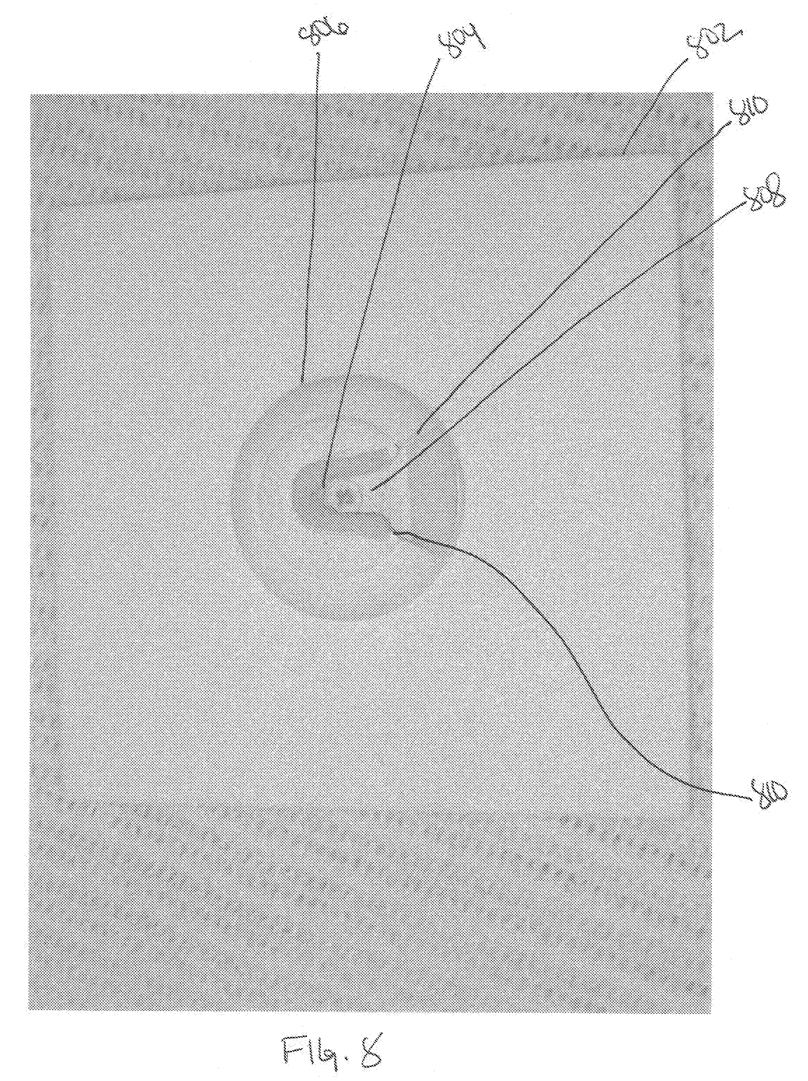

Referring now to FIG. 8, a portable tile 802 with an insertion point 804 designed for a male ball-type terminus 130 to slide into for suspension from a ceiling 302 is shown.

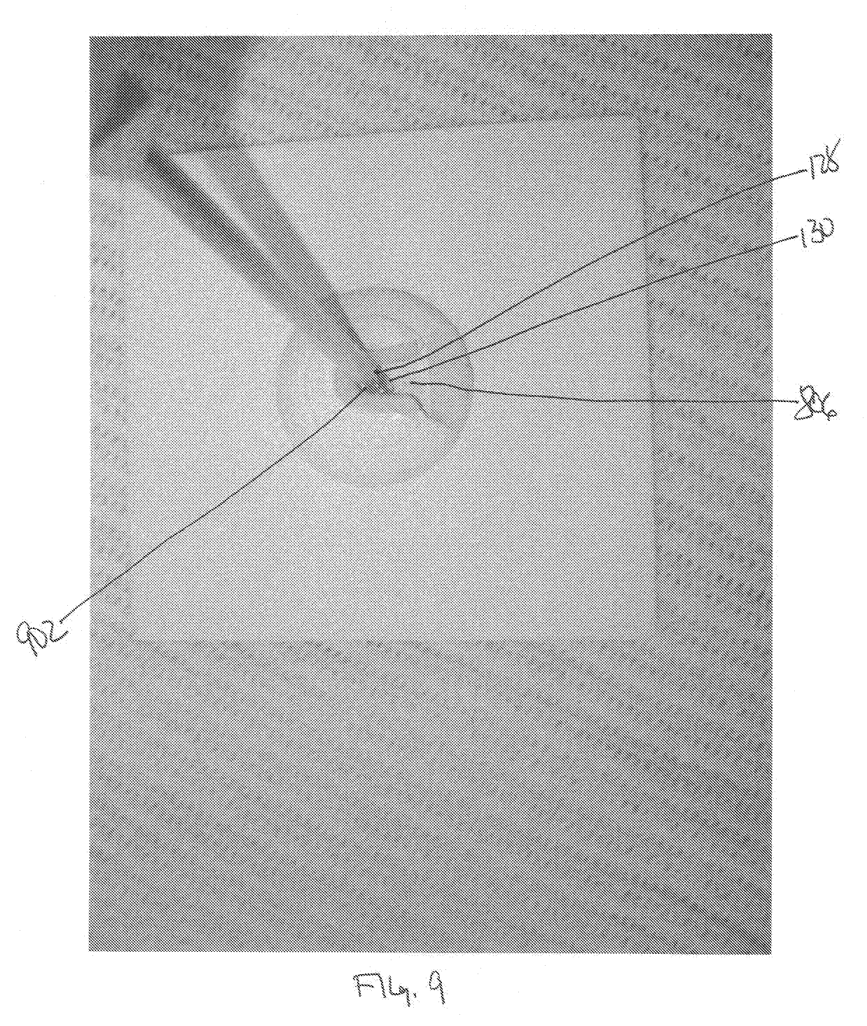

Referring now to FIG. 9, a male ball-type terminus 130 attached to a stem 122 is shown inserted into the channel 808, creating a ball-and-socket joint 902.

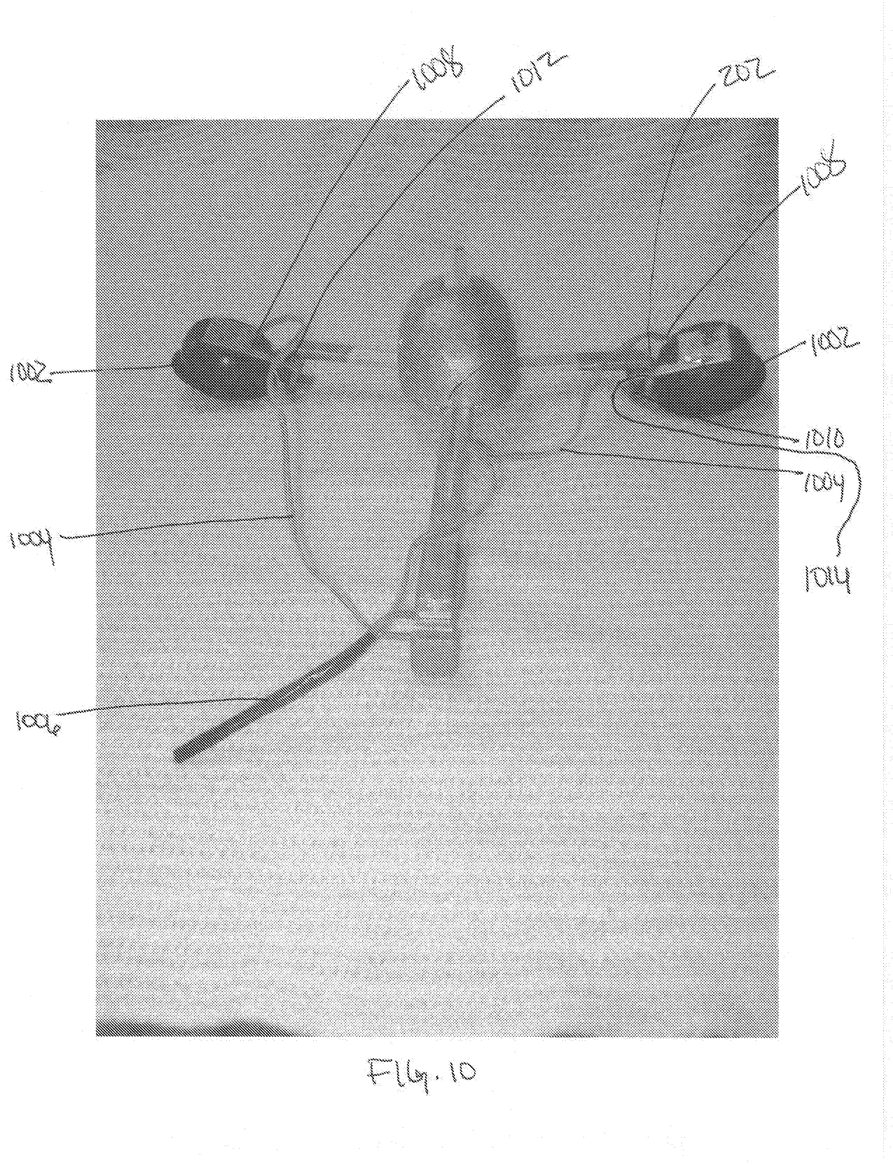

Referring now to FIG. 10, a monitor holder 100 is shown with two commercially available speakers 1002 with commercially available speaker wiring 1004 electrically connected thereto.

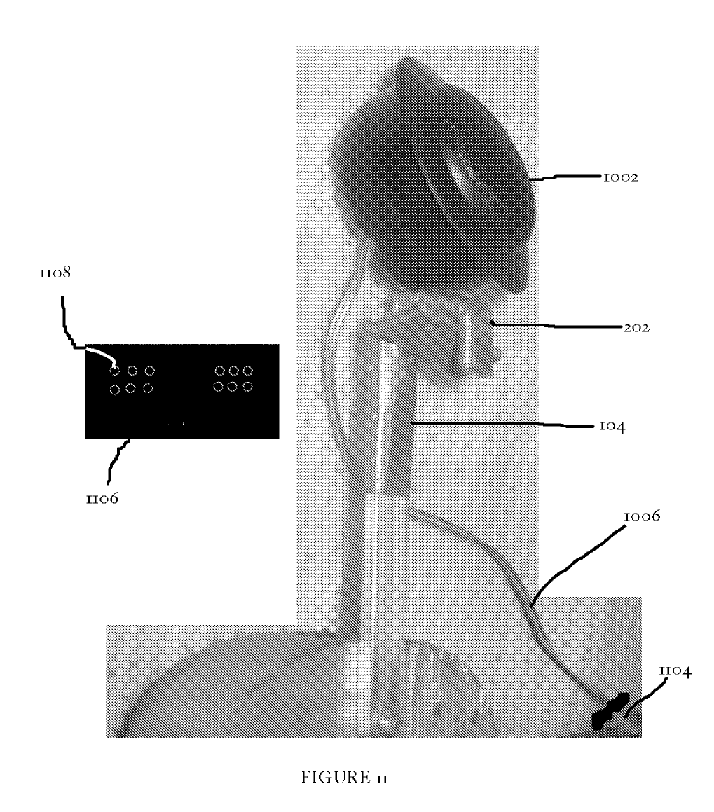

Referring now to FIG. 11, an outside view of an L- or J-joint 1010 affixing a speaker 1002 to the curved or hooked end 202 of a hinged arm 104 of a monitor holder 100 is shown.

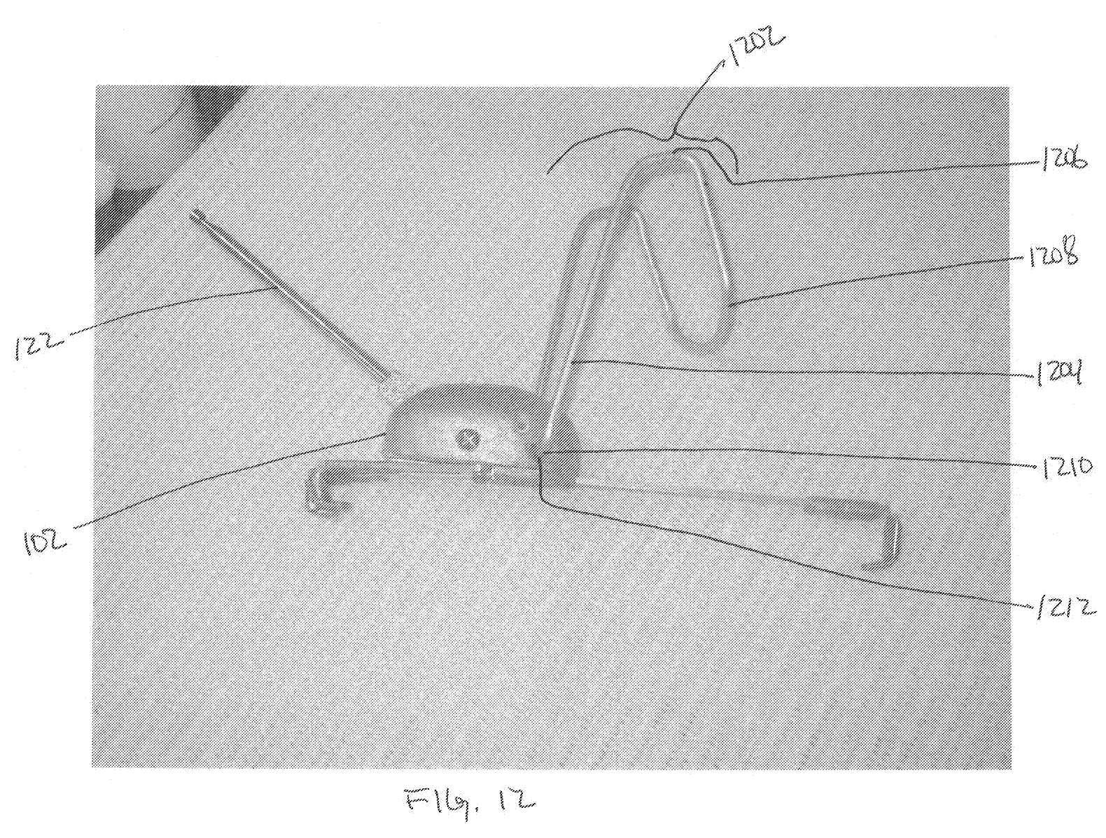

Referring now to FIG. 12, a side view of a monitor holder 100 with an optional attachment 1202 for hanging the monitor holder 100 is shown.

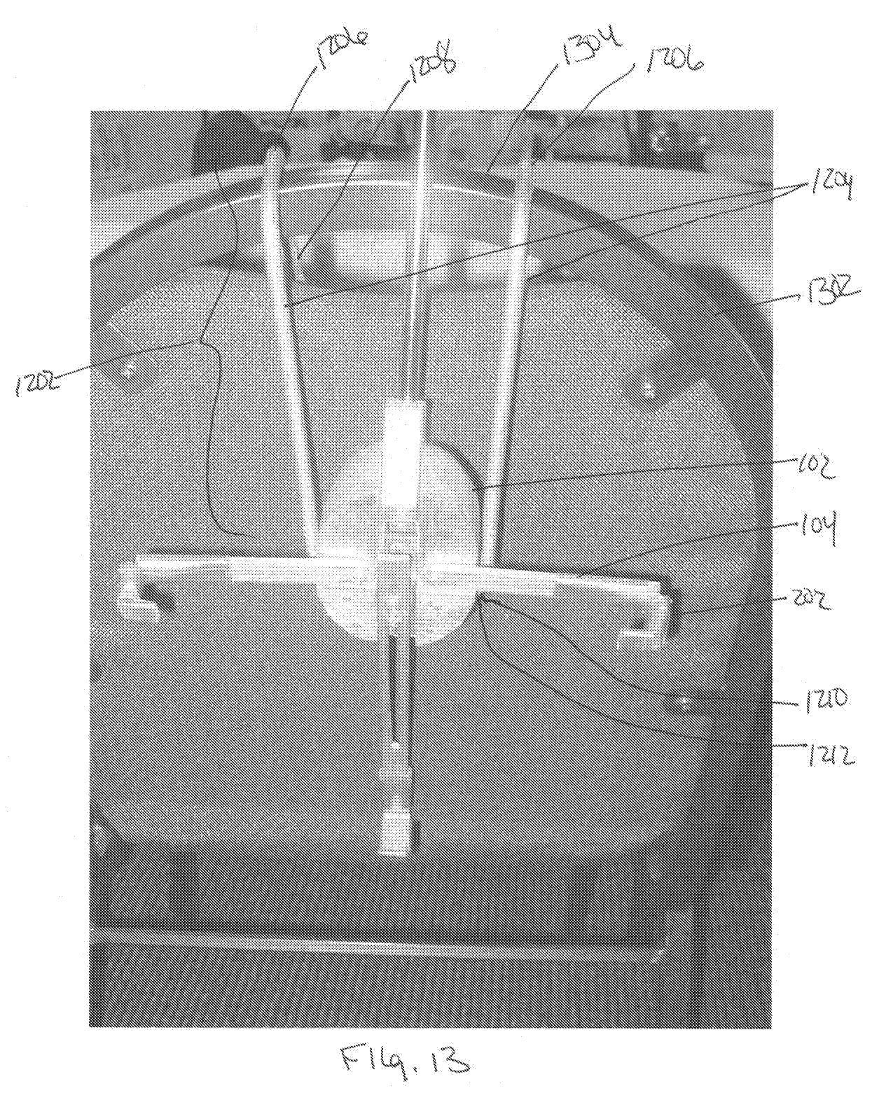

Referring now to FIG. 13, a monitor holder 100 hanging from a vertical object 1302 using an optional 1202 is shown.

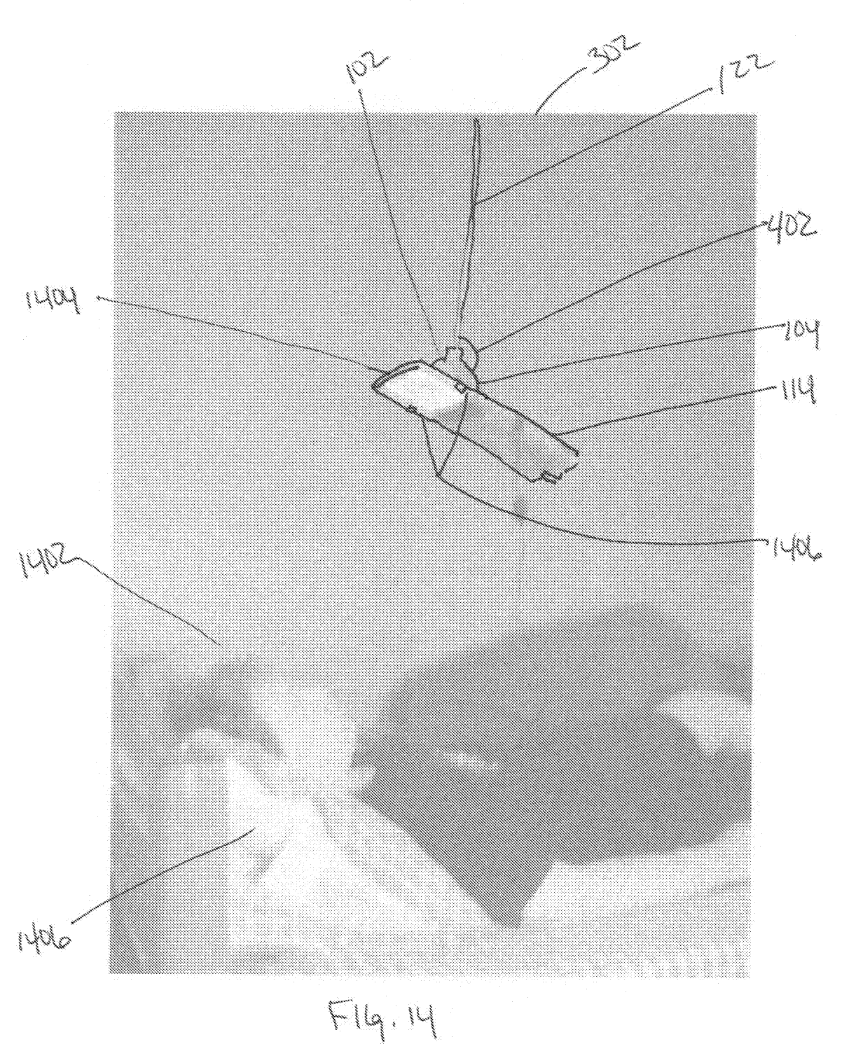

Referring now to FIG. 14, a person 1402 using a monitor holder 100 to view a flat-screen monitor 1404 from a comfortable position is shown.

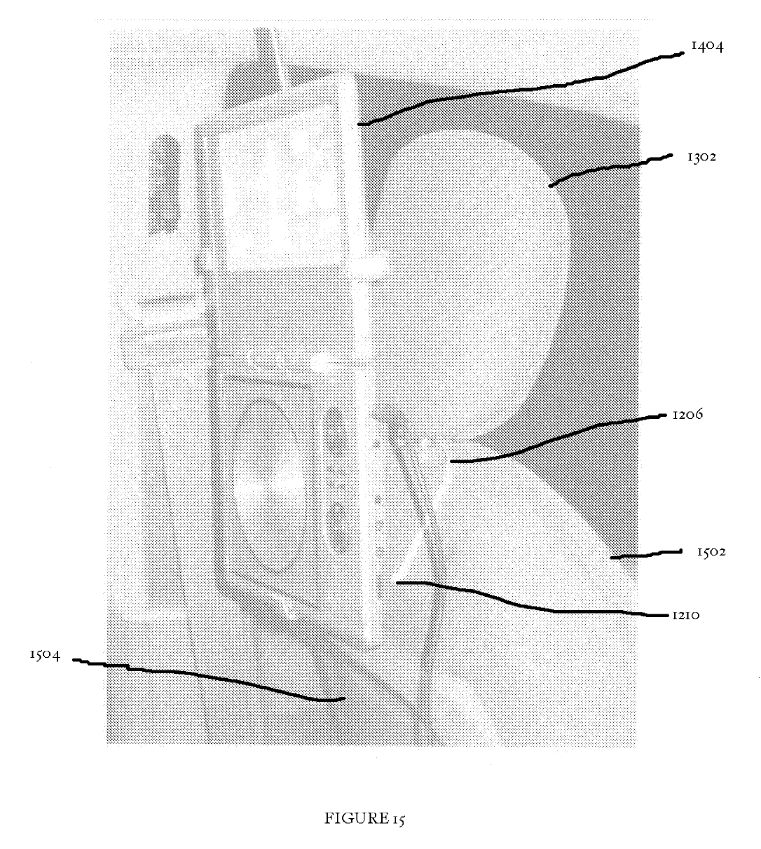

Referring now to FIG. 15, a monitor holder 100 mounted on a vertical object 1302 and holding a flat-screen monitor 1404 for viewing is shown.

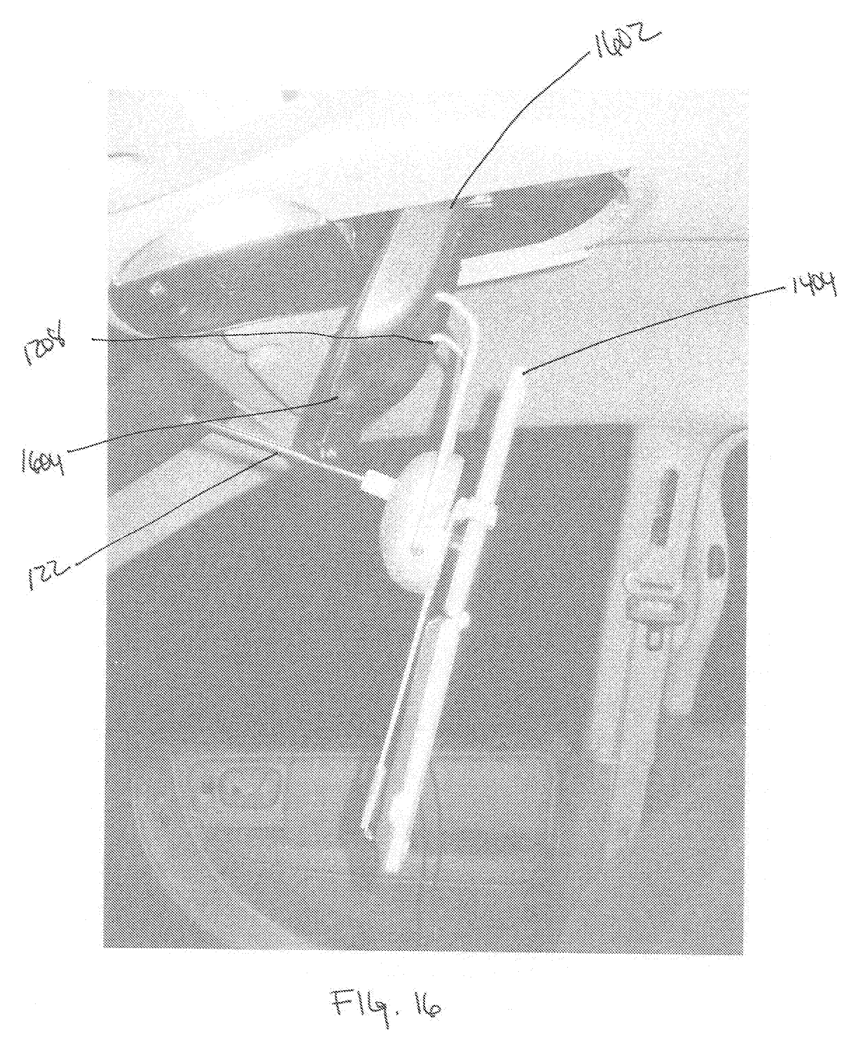

Referring now to FIG. 16, a monitor holder 100 mounted on a drop-down cupped object 1602 and holding a flat-screen monitor 1404 for viewing is shown.

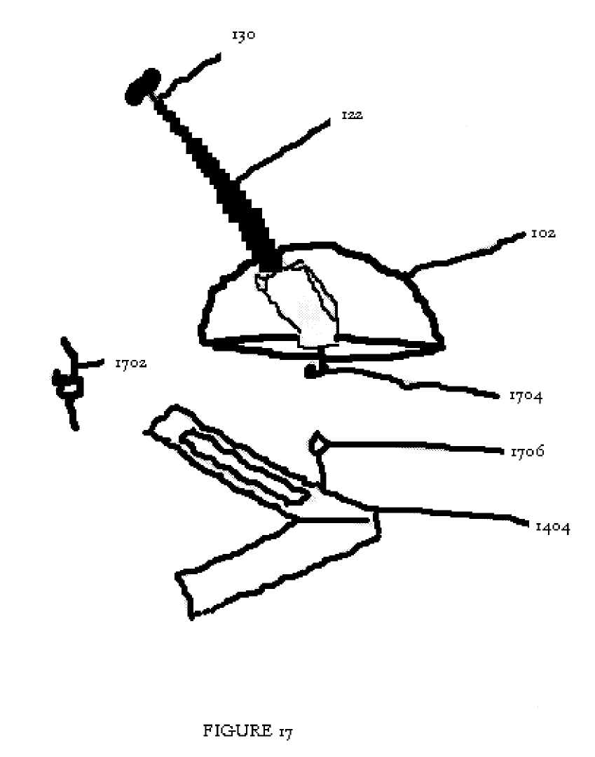

Referring now to FIG. 17, a monitor holder 100 configured to hold a monitor 1404 by a hook-and-eye system 1702 is shown.

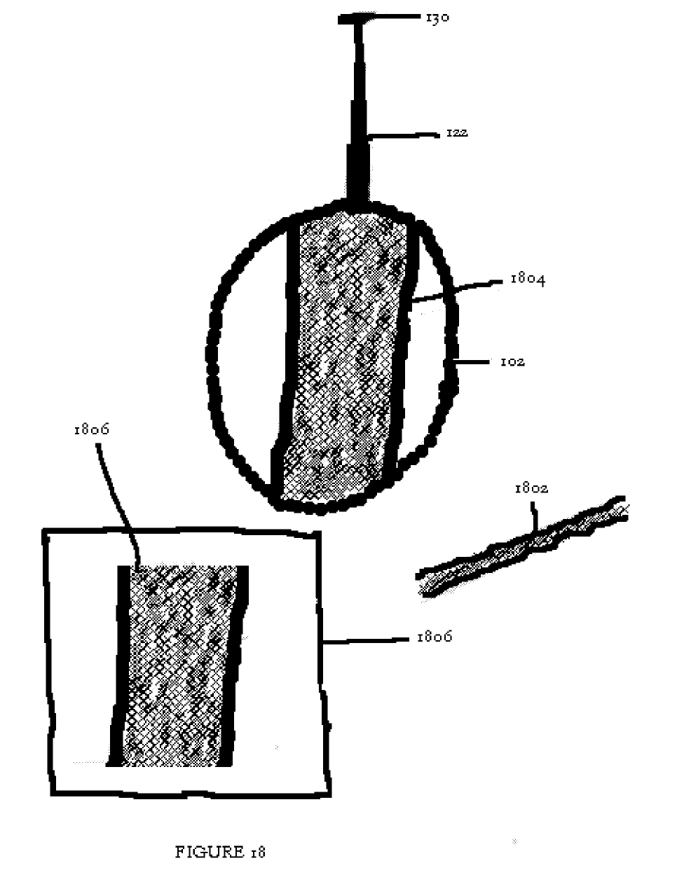

Referring now to FIG. 18, a monitor holder 100 configured to hold a monitor 1404 by a fabric- or plastic-based tangled-thread hook-and-eye system 1802 is shown.

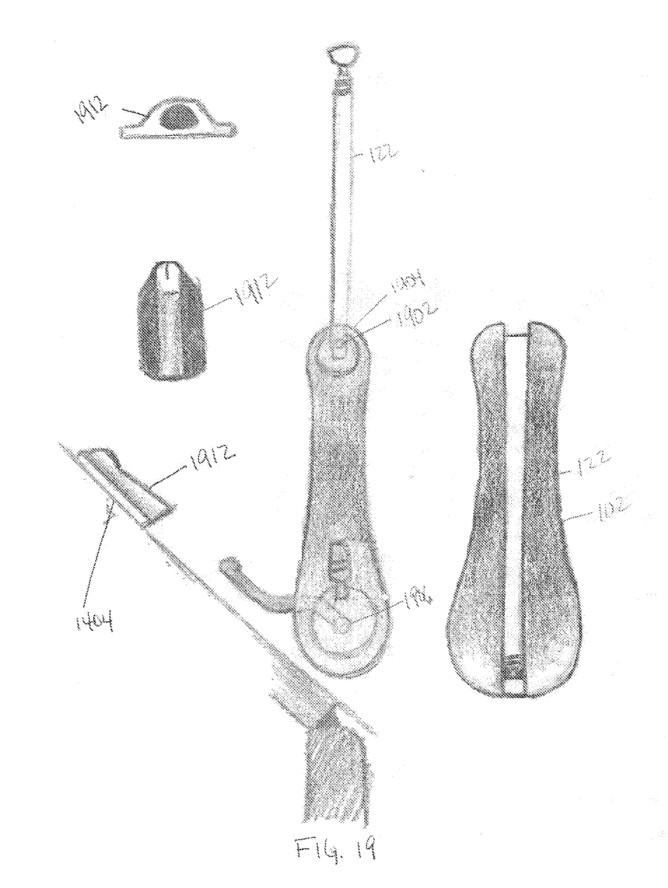

Referring now to FIG. 19, a monitor holder 100 is shown in a configuration wherein a stem end connecting screw 1902 holds the stem end 1904 of the body 102 together.

### DETAILED DESCRIPTION OF THE INVENTION

Referring now to FIG. 1, a suspendable, portable monitor holder 100 is shown, comprising a body 102, said body being composed of an element selected from the group consisting of wood, plastic, rock, mineral, and metal; two hinged arms 104 each consisting of a hinged arm body end 106, a hinged arm midsection 108, and a hinged arm distal end 110, said hinged arms 104 extending outward in a substantially 180-degree angle each from the other when in position for use and folding to a substantially zero-degree angle for storage, said hinged arms being composed of an element selected from the group consisting of wood, plastic, rock, mineral, and metal; two hinged arm hinges 112 each of which hingedly affixes one of said hinged arm body ends 106 to said body 102 such that said hinged arms 104 form a substantially 180-degree angle each from the other when extended, and a substantially zero-degree angle one from the other when collapsed; a supporting arm 114 consisting of a supporting arm body end 116, a supporting arm midsection 118, and a supporting arm distal end 120, said supporting arm 114 extending from said body 102 in substantially the same plane as said hinged arms 104 and being substantially perpendicular to said hinged arms 104 when said hinged arms 104 are in position for use, said supporting arm being composed of an element selected from the group consisting of wood, plastic, rock, mineral, and metal; a stem 122 consisting of a stem body end 124, a stem midsection 126, and a stem distal end 128, said distal end comprising a ball-type terminus 130, said stem being composed of an element selected from the group consisting of wood, plastic, rock, mineral, and metal; and a stem hinge 132 that hingedly affixes said stem body end 124 to said body 102, said stem hinge 132 being capable of moving substantially 180 degrees in one plane.

The hinged arms 104 may be of a fixed length sufficient to hold one particular size of flat-screen monitor, or they may be of variable length, enabling them to hold monitors of different dimensions.

The supporting arm 114 is of variable length; the supporting arm 114 may be retracted toward the body 102 for storage, or the supporting arm 114 may be extended to support the bottom side of a monitor. In another embodiment, the supporting arm 114 may be of a fixed length.

Referring now to FIG. 2, an inside view of a monitor holder 100 is shown. The hinged arms 104 terminate away from the body 102 in hooked or curved ends 202. The supporting arm 114 also terminates in a curve or hook 204. The hinged arm hinges 112 are comprised of a screw, bolt, or dowel 206 that allows them to move freely in a flat plane that is substantially perpendicular to the plane described by the stem hinge 132. The stem 122 is shown as a telescoping rod in the current embodiment, but the stem 122 may be of a fixed length and still be within the scope of the invention. The male ball-type terminus 130 is shown at the end of the stem 122.

Referring now to FIG. 3, a monitor holder 100 suspended by a stem 122 from a ceiling 302 is shown. In this figure, the suspension mechanism 304 is a mutual magnetic attraction between the stem 122 and the ceiling beam 306. Note that the magnetic attraction must be sufficient to hold the monitor holder 100 and any item being held by the monitor holder 100.

Referring now to FIG. 4, a monitor holder 100 hanging from a ceiling 302 is shown. The monitor holder 100 is held at an angle 402 described by the stem hinge 132 and the body 102. The angle 402 may be any size to hold that is comfortable for a human viewer.

Referring now to FIG. 5, a stem hinge 132 in the body 102 of a monitor holder 100 is shown. The stem hinge 132 consists of a freely rotating bracket 502 that is swingingly affixed to a bracket element 504 selected from the group consisting of a bolt and a dowel. The bracket is permanently affixed with a stem element 506 selected from the group consisting of a bolt and a dowel to the stem 122. The stem hinge 132 is held in place by friction between the stem base 508 and the sides 510 of a negative space 512 within the body 102. The negative space 512 allows the stem hinge 132 that attaches the stem 122 to the body 102 to move freely within a single plane to any position relative to the body 102 such that a human user can select any angle 402 at which to use the monitor holder 100.

Referring now to FIG. 6, a casing 602 in which a monitor holder 100 can be easily stored and transported is shown. The casing 602 may have optional grips 604 to make carrying a monitor holder 100 easier. The casing may have an opening 606 to make inserting a monitor holder 100 into the casing 602 easy.

Referring now to FIG. 7, a casing 602 is shown. A monitor holder 100 is held in place within the casing 602 by a set of holders 702.

Referring now to FIG. 8, a portable ceiling tile 802 with an insertion point 804 designed for a male ball-type terminus 130 to slide into for suspension from a ceiling 302 is shown. In the current embodiment, the attachment 806 is comprised of a channel 808 formed by a cut-out 810 from the attachment 806 such that an object such as a male ball-type terminus 130 can be slid into the channel easily from any position below the ceiling tile 802 and securely held within the insertion point 804.

Referring now to FIG. 9, a male ball-type terminus 130 attached to a stem distal end 128 is shown inserted into the channel 808, creating a ball-and-socket joint 902. Note that the channel 808 must be large enough to accommodate the male ball-type terminus 130, but small enough to hold the male ball-type terminus 130 within the ball-and-socket joint 902. In this configuration, the male ball-type terminus 130 holds the monitor holder 100 securely suspended but allows the monitor holder 100 to swing freely in all planes.

Referring now to FIG. 10, a monitor holder 100 is shown with two commercially available speakers 1002 with commercially available speaker wiring 1004 electrically connected thereto. The wiring 1004 terminates at a non-speaker end 1006 that is designed to be electrically connected a commercially available speaker system (not shown). The wiring 1004 also has a speaker end 1008 that electrically connects to each speaker 1002.

Each speaker 1002 has affixed to it a sliding L- or J-joint 1010 that can be hookingly or slidingly engaged with the curved or hooked end 202 of a hinged arm 104. In the embodiment shown, the joint 1010 is held in place by friction. It is within the scope of the invention, however, that the joint 1010 may be held in place by a fabric- or plastic-based tangled-thread hook-and-eye connection system 1012, or that the speaker 1002 may be permanently affixed to the hinged arm end 202 using a speaker connection element selected from the group consisting of a ball-and-socket joint, a screw, a bolt, and a dowel 1014.

Referring now to FIG. 11, an outside view of an L- or J-joint 1010 affixing a speaker 1002 to the curved or hooked end 202 of a hinged arm 104 of a monitor holder 100 is shown. The speaker 1002 rests outside of the curved or hooked end 202 of the hinged arm 104, and an L- or J-joint 1010 that is permanently affixed to the speaker 1002 fits hookingly into the curved or hooked end 202. Friction or compression holds the L- or J-joint 1010 into the curved or hooked end 202.

In another embodiment, the speaker 1002 may be permanently affixed to the hinged arms 104 by using a speaker attachment element 1102 selected from the group consisting of a screw, a dowel, and a bolt to fasten the L- or J-joint 1010 to the curved or hooked end 202. In a permanent affixation, a human user requires a way to quickly and easily electrically connect speaker wire 1004 to a commercially available sound system 1106. Such plug-in connections 1104 can be affixed to the non-speaker end 1006 of the speaker wire 1004, and plug into a jack 1108 within the sound system 1106. Such plug-in connectors 1104 are well known in the art, and are readily available commercially.

Referring now to FIG. 12, a side view of a monitor holder 100 with an optional attachment 1202 for hanging the monitor holder 100 is shown. The attachment 1202 comprises a shaft 1204, a bend 1206, a hook 1208, and two hinging ends 1210 that insert into a foramen 1212 within the body 102 such that the attachment swings freely in the same plane in which the stem 122 swings, but the attachment 1202 is at the opposite end of the body 102 from the stem 122.

The current embodiment shows the hinging ends 1210 as being slidingly inserted into foramina 1212 on either side of the body 102. It is within the scope of the invention, however, for the attachment 1202 to be continuous; the hinging ends 1210 are then connected one to the other, forming a bar 1214 that passes through the body 102, and the foramina 1212 are extended through the body 102 to accommodate the bar 1214.

Referring now to FIG. 13, a monitor holder 100 hanging from a vertical object 1302 using an optional attachment 1202 is shown. The bend 1206 is in contact with the high point 1304 of the vertical object 1302, and the hook 1208 holds the bend 1206 in place on the vertical object 1302. The shafts 1204 securely insert into foramina 1212 within the body 102 by means of hinging ends 1210. The bend 1206 is directed away from the body 102 such that the curved or hooked ends 202 of the hinging arms 104 are facing away from the optional attachment 1202.

Referring now to FIG. 14, a person 1402 using a monitor holder 100 to view a flat-screen monitor 1404 from a comfortable position is shown. The monitor holder 100 is suspended from a ceiling 302 either magnetically using a ceiling beam 306 or by using a portable tile 802 (not shown) by suspending the monitor holder 100 by the stem 122 from the ceiling 302. The person 1402 is shown using comfortable seating 1406, which may be an easy chair, a bed, a sofa, or any other seating, with the monitor holder 100 set at an angle 402.

Hinged arms 104 extend outward from the center of the body 102 to hold the monitor 1404 on each side 1406 of the monitor 1404 in the curved or hooked ends 202. The support arm distal end 120 holds the bottom of the monitor 1404 securely in place with its curved or hooked end 204 and prevents the monitor 1404 from falling or becoming disengaged from the monitor holder 100.

Referring now to FIG. 15, a monitor holder 100 mounted on a vertical object 1302 and holding a flat-screen monitor 1404 for viewing is shown. In the current embodiment, the monitor holder 100 is mounted on a car's front seat 1502. The optional attachment 1202 is in use, with the bend 1206 looped over the headrest 1502 of the car's seat 1502. The body 102 hangs from the hinged ends 1210, which are inserted into the foramina 1212, against the back 1504 of the car's seat 1502.

Referring now to FIG. 16, a monitor holder 100 mounted on a drop-down cupped object 1602 and holding a flat-screen monitor 1404 for viewing is shown. The hook 1208 of the optional attachment 1202 is restingly inserted within the cupped object 1602, such that the hook 1208 of the attachment 1202 rests on the bottom 1604 of the cupped object 1602 and holds the monitor holder 100 in place. The stem 122 rests against the bottom 1604 of the cupped object 1602 and prevents the monitor 1404 from swinging back and forth.

Referring now to FIG. 17, a monitor holder 100 configured to hold a monitor 1404 by a hook-and-eye system 1702 is shown. A hook 1704 is permanently affixed to the body 102. To use the system, the hook 1704 is hookingly engaged with an eye 1706 that is permanently affixed to the monitor 1404. No hinged arms 104 or supporting arm 114 is used in this embodiment.

In an alternate embodiment, the hook 1704 may be permanently affixed to the monitor 1404 and the eye 1706 may be permanently affixed to the body 102.

The monitor 1404 may be held at an angle 402 by resting a monitor edge 1808 against a stable object 1810 such as a wall or a chair.

In an alternate embodiment, the hook-and-eye system 1702 may be configured such that a user-selected angle 402 is maintained by the engagement of the hook 1704 with the eye 1706.

Referring now to FIG. 18, a monitor holder 100 configured to hold a monitor 1404 by a fabric- or plastic-based tangled-thread hook-and-eye system 1802 is shown. The tangled-thread hook-and-eye system 1802 has two components: one component is a tangled thread strip 1804; the other component is a miniature hook strip 1806. The tangled thread strip 1804 is pressed into the miniature hook strip 1806 to produce a secure holder for the monitor 1404 on the body 102.

A length of tangled thread strip 1804 of sufficient length to produce the strength to hold the monitor 1404 in place upon the body 102 is permanently affixed, perhaps with glue, to the back side 1808 of the monitor 1404. A similar length of miniature hook strip is permanently affixed, perhaps with glue or with tacks, to the underside 1810 of the body 102. The body 102 and the monitor 1404 can then be pressed together by the affixed strips 1804,1806 to hold the monitor firmly in place upon the body 102.

Referring now to FIG. 19, a monitor holder 100 is shown in a configuration wherein a stem end connecting screw 1902 holds the stem end 1904 of the body 102 together. The stem 122 pivotally affixed to the stem end connecting screw 1902 and extends outward from the body 102. A pivoting arm end connecting screw 1906 holds two pivoting arm end halves 1908 of the body 102 together. A pivoting arm 1910 is pivotally attached to the pivoting arm end connecting screw 1906 such that the pivoting arm 1910 can be extended outward from the body 102 to any angle set by a user. The pivoting arm 1910 then slides into a channel 1912 that is permanently affixed to a flat-screen monitor 100.

The stem 122 can be folded into the body 100 for storage.

In an alternate embodiment, tangled thread strip 1804 of sufficient length to produce the strength to hold the monitor 1404 in place upon the body 102 is permanently affixed, perhaps with glue or with tacks, to the body 102, and a miniature hook strip 1804 of similar length is permanently affixed, perhaps by gluing, to the monitor 1404.

The embodiments provided here are examples only and are not intended to be a complete listing of possible embodiments, nor should they be construed as an exclusive listing of embodiments. Variations in the described invention and its uses are possible within the scope of this disclosure without departing from the subject matter coming within the scope of claims to be examined, and a reasonable equivalency thereof, which I regard as my invention.

I claim:

1. A suspendable, portable holder for a flat-panel monitor comprising:
a body 102, said body being composed of an element selected from the group consisting of wood, plastic, rock, mineral, and metal;
two hinged arms 104 each consisting of a hinged arm body end 106, a hinged arm midsection 108, and a hinged arm distal end 110, said hinged arms 104 extending outward in a substantially 180-degree angle each from the other when in position for use and folding to a substantially zero-degree angle for storage, said hinged arms being composed of an element selected from the group consisting of wood, plastic, rock, mineral, and metal;
a mechanism for holding a monitor 1404 closely to said body 102;
a stem 122 consisting of a stem body end 124, a stem midsection 126, and a stem distal end 128, said distal end comprising a ball-type terminus 130, said stem being composed of an element selected from the group consisting of wood, plastic, rock, mineral, and metal; and
a stem hinge 132 that hingedly affixes said stem body end 124 to said body 102, said stem hinge 132 being capable of moving substantially 180 degrees in one plane.

2. The holder of claim 1 further comprising said mechanism for holding said monitor 1404 closely to said body 102 being two hinged arm hinges 112 each of which hingedly affixes one of said hinged arm body ends 106 to said body 102 such that said hinged arms 104 form a substantially 180-degree angle each from the other when extended, and a substantially zero-degree angle one from the other when collapsed and a supporting arm 114 consisting of a supporting arm body end 116, a supporting arm midsection 118, and a supporting arm distal end 120, said supporting arm 114 extending from said body 102 in substantially the same plane as said hinged arms 104 and being substantially perpendicular to said hinged arms 104 when said hinged arms 104 are in position for use, said supporting arm being composed of an element selected from the group consisting of wood, plastic, rock, mineral, and metal;

3. The holder of claim 2 further comprising said hinged arms being of fixed length.

4. The holder of claim 2 further comprising said hinged arms being of variable length.

5. The holder of claim 2 further comprising said supporting arm being of fixed length.

6. The holder of claim 2 further comprising said supporting arm being of variable length.

7. The holder of claim 2 further comprising said hinged arms distal end 110 being hooked or curved.

8. The holder of claim 2 further comprising said supporting arm distal end being hooked or curved.

9. The holder of claim 1 further comprising said stem 122 being composed of a telescoping rod.

10. The holder of claim 1 further comprising said stem 122 being of a fixed length.

11. The holder of claim 1 further comprising said holder 100 being suspended by said stem 122 from a ceiling.

12. The holder of claim 11 further comprising said stem 122 having a magnetic field sufficient to hold said monitor holder 100 and any item being held by the monitor holder 100 suspended from said ceiling.

13. The holder of claim 11 further comprising said holder 100 being suspended from a portable ceiling tile 802 with an insertion point 804 designed for a male ball-type terminus 130 to slide into for suspension from a ceiling 302.

14. The holder of claim 13 further comprising said insertion point 804 being comprised of a channel 808 formed by a cut-out 810 from said attachment 806 such that an object such as a male ball-type terminus 130 can be slid into the channel easily from any position below the ceiling tile 802 and securely held within said insertion point 804.

15. The holder of claim 1 further comprising said monitor holder 100 being held at an angle 402 described by the stem hinge 132 and the body 102, said angle 402 being of any size that is comfortable for a human viewer.

16. The holder of claim 15 further comprising the method for holding said angle 402 being friction.

17. The holder of claim 1 further comprising two commercially available speakers 1002 with commercially available speaker wiring 1004 electrically connected thereto, said wiring 1004 terminating at a non-speaker end 1006 that is designed to be electrically connected a commercially available speaker system and at a speaker end 1008 that electrically connects to each speaker 1002.

18. The holder of claim 17 further comprising each of said speakers 1002 having affixed to it a sliding L- or J-joint 1010 that can be hookingly or slidingly engaged with the curved or hooked end 202 of a hinged arm 104.

19. The holder of claim 18 further comprising said joint 1010 being held in place by friction.

20. The holder of claim 18 further comprising said joint 1010 being held in place by a fabric- or plastic-based tangled-thread hook-and-eye connection system 1012

21. The holder of claim 18 further comprising said speakers 1002 being permanently affixed to said hinged arm end 202 using a speaker connection element 1014 selected from the group consisting of a ball-and-socket joint, a screw, a bolt, and a dowel.

22. The holder of claim 18 further comprising plug-in connections 1104 that can be affixed to said non-speaker end 1006 of said speaker wire 1004, and plug into a jack 1108 within a sound system 1106.

23. The holder of claim 1 further comprising an optional attachment 1202 for hanging the monitor holder 100, said attachment 1202 comprising a shaft 1204, a bend 1206, a hook 1208, and two hinging ends 1210 that insert into a foramen 1212 within said body 102 such that said attachment swings freely in the same plane in which said stem 122 swings, said attachment 1202 being located at the opposite end of the body 102 from said stem 122.

24. The holder of claim 23 further comprising said attachment 1202 being used to hang said holder 100 from a vertical object 1302.

25. The holder of claim 1 further comprising said mechanism for holding said monitor 1404 to said body 102 being a hook-and-eye system 1702, said system 1702 being composed of a permanently affixed hook 1704 and a permanently affixed eye 1706, said hook 1704 and eye 1706 being hookingly engaged to hold said monitor 1404 to said body 102.

26. The holder of claim 25 further comprising said hook being permanently affixed to said monitor and said eye being permanently affixed to said body.

27. The holder of claim 25 further comprising said hook being permanently affixed to said body and said eye being permanently affixed to said monitor.

28. The holder of claim 1 further comprising said mechanism for holding said monitor 1404 to said body 102 being a tangled thread hook-and-eye system 1802, said system 1802 being composed of a permanently affixed tangled thread strip 1804 and a permanently affixed miniature hook strip 1806, said strips 1804,1806 being hookingly engaged to hold said monitor 1404 to said body 102.

29. The holder of claim 28 further comprising said tangled thread strip being permanently affixed to said body and said miniature hook strip being permanently affixed to said monitor.

30. The holder of claim 28 further comprising said tangled thread strip being permanently affixed to said monitor and said miniature hook strip being permanently affixed to said body.

31. A suspendable, portable holder for a flat-panel monitor comprising:
a body 102, said body being composed of an element selected from the group consisting of wood, plastic, rock, mineral, and metal;
a mechanism for holding a monitor 1404 closely to said body 102;
a stem 122 consisting of a stem body end 124, a stem midsection 126, and a stem distal end 128, said distal end comprising a ball-type terminus 130, said stem being composed of an element selected from the group consisting of wood, plastic, rock, mineral, and metal;
two commercially available speakers 1002 with commercially available speaker wiring 1004 electrically connected thereto, said wiring 1004 terminating at a non-speaker end 1006 that is designed to be electrically connected a commercially available speaker system and at a speaker end 1008 that electrically connects to each speaker 1002 affixed to said holder 100, each of said speakers 1002 having affixed to it a sliding L- or J-joint 1010 that can be hookingly or slidingly engaged with the curved or hooked end 202 of a hinged arm 104; and
a stem hinge 132 that hingedly affixes said stem body end 124 to said body 102, said stem hinge 132 being capable of moving substantially 180 degrees in one plane.

32. The holder of claim 31 further comprising said mechanism for holding said monitor 1404 closely to said body 102 comprising two hinged arm hinges 112 each of which hingedly affix each of two hinged arm body arms 104 to said body 102 such that said hinged arms 104 are affixed by hinged arm body ends 106 and each hinged arm distal end 108 is curved or hooked, said hinged arms 104 forming a substantially 180 degree angle each from the other when extended, and a substantially zero-degree angle one from the other when collapsed and a supporting arm 114 consisting of a supporting arm body end 116, a supporting arm midsection 118, and a curved or hooked supporting arm distal end 120, said supporting arm 114 extending from said body 102 in substantially the same plane as said hinged arms 104 and being substantially perpendicular to said hinged arms 104 when said hinged arms 104 are in position for use, said supporting arm being composed of an element selected from the group consisting of wood, plastic, rock, mineral, and metal;

33. The holder of claim 32 further comprising said hinged arms being of fixed length.

34. The holder of claim 32 further comprising said hinged arms being of variable length.

35. The holder of claim 32 further comprising said supporting arm being of fixed length.

36. The holder of claim 32 further comprising said supporting arm being of variable length.

37. The holder of claim 31 further comprising said stem 122 being composed of a telescoping rod.

38. The holder of claim 31 further comprising said stem 122 being of a fixed length.

39. The holder of claim 31 further comprising said holder 100 being suspended by said stem 122 from a ceiling.

40. The holder of claim 39 further comprising said stem 122 having a magnetic field sufficient to hold said monitor holder 100 and any item being held by the monitor holder 100 suspended from said ceiling.

41. The holder of claim 39 further comprising said holder 100 being suspended from a portable ceiling tile 802 with an insertion point 804 designed for a male ball-type terminus 130 to slide into for suspension from a ceiling 302, said insertion point 804 being comprised of a channel 808 formed by a cut-out 810 from said attachment 806 such that an object such as a male ball-type terminus 130 can be slid into the channel easily from any position below the portable ceiling tile 802 and securely held within said insertion point 804.

42. The holder of claim 31 further comprising said monitor holder 100 being held at an angle 402 described by the stem hinge 132 and the body 102, said angle 402 being of any size that is comfortable for a human viewer, a method for holding said angle 402 being friction.

43. The holder of claim 31 further comprising said joint 1010 being held in place by a fabric-or plastic-based tangled-thread hook-and-eye connection system 1012

44. The holder of claim 31 further comprising said speakers 1002 being permanently affixed to said hinged arm end 202 using a speaker connection element 1014 selected from the group consisting of a ball-and-socket joint, a screw, a bolt, and a dowel.

45. The holder of claim 31 further comprising plug-in connections 1104 that can be affixed to said non-speaker end 1006 of said speaker wire 1004, and plug into a jack 1108 within a sound system 1106.

46. The holder of claim 31 further comprising an optional attachment 1202 for hanging the monitor holder 100, said attachment 1202 comprising a shaft 1204, a bend 1206, a hook 1208, and two hinging ends 1210 that insert into a foramen 1212 within said body 102 such that said attachment swings freely in the same plane in which said stem 122 swings, said attachment 1202 being located at the opposite end of the body 102 from said stem 122, said attachment 1202 being used to hang said holder 100 from a vertical object 1302.

47. The holder of claim 31 further comprising said mechanism for holding said monitor 1404 to said body 102 being a hook-and-eye system 1702, said system 1702 being composed of an element selected from the group consisting of a set consisting of a permanently affixed hook 1704 and a permanently affixed eye 1706, said hook 1704 and eye 1706 being hookingly engaged to hold said monitor 1404 to said body 102; a set consisting of a tangled thread hook-and-eye system 1802, said system 1802 being composed of a permanently affixed tangled thread strip 1804 and a permanently affixed miniature hook strip 1806, said strips 1804,1806 being hookingly engaged to hold said monitor 1404 to said body 102; and a set consisting of a pair of hinged arms and a supporting arm.

48. The holder of claim 31 further comprising said mechanism for holding said monitor 1404 to said body 102 being comprised of a stem end connecting screw 1902 holding two halves of a stem end 1904 of said body 102 together, wherein said stem 122 is pivotally affixed to said stem end connecting screw 1902 and extends outward from said body 102, and a pivoting arm end connecting screw 1906 holds two pivoting arm end halves 1908 of said body 102 together and a pivoting arm 1910 being pivotally attached to said pivoting arm end connecting screw 1906 such that said pivoting arm 1910 can be extended outward from said body 102 to any angle set by a user, and wherein said pivoting arm 1910 can slide into a channel 1912 that is permanently affixed to a flat-screen monitor 100.

49. A suspendable, portable holder for a flat-panel monitor comprising:
a body 102, said body being composed of an element selected from the group consisting of wood, plastic, rock, mineral, and metal;
a mechanism for holding a monitor 1404 closely to said body 102, said mechanism being an element selected from the group consisting of
a hook-and-eye system,
a tangled-thread hook-and-eye system,
a stem end connecting screw 1902 holding two halves of a stem end 1904 of said body 102 together, wherein said stem 122 is pivotally affixed to said stem end connecting screw 1902 and extends outward from said body 102, and a pivoting arm end connecting screw 1906 holds two pivoting arm end halves 1908 of said body 102 together and a pivoting arm 1910 being pivotally attached to said pivoting arm end connecting screw 1906 such that said pivoting arm 1910 can be extended outward from said body 102 to any angle set by a user, and wherein said pivoting arm 1910 can slide into a channel 1912 that is permanently affixed to a flat-screen monitor 100, and
a set consisting of two hinged arms and a supporting arm;
a stem 122 consisting of a stem body end 124, a stem midsection 126, and a stem distal end 128, said distal end comprising a ball-type terminus 130, said stem being composed of an element selected from the group consisting of wood, plastic, rock, mineral, and metal, and said stem being of either variable or of fixed length;
a portable ceiling tile to which an attachment for holding a male ball-type terminus is affixed;
two commercially available speakers 1002 with commercially available speaker wiring 1004 electrically connected thereto, said wiring 1004 terminating at a non-speaker end 1006 that is designed to be electrically connected a commercially available speaker system using commercially available speaker plugs, and at a speaker end 1008 that electrically connects to each speaker 1002 affixed to said holder 100;
an optional attachment for suspending said body on a vertical object;
a stem hinge 132 that hingedly affixes said stem body end 124 to said body 102, said stem hinge 132 being capable of moving substantially 180 degrees in one plane and holding said body firmly in a plane set by a human user using friction.
